(19) United States
(12) Patent Application Publication
(10) Pub. No.: US 2020/0395514 A1
(43) Pub. Date: Dec. 17, 2020

(54) LIGHT EMITTING DEVICE PACKAGE

(71) Applicant: LG INNOTEK CO., LTD., Seoul (KR)

(72) Inventors: Suk Kyung PARK, Seoul (KR); Chang Man LIM, Seoul (KR); June O SONG, Seoul (KR); Jung Hwa JUNG, Seoul (KR)

(21) Appl. No.: 16/955,213

(22) PCT Filed: Oct. 23, 2018
(86) PCT No.: PCT/KR2018/012542

§ 371 Date: Jun. 18, 2020

(30) Foreign Application Priority Data
Dec. 19, 2017 (KR) 10-2017-0175538

(51) Int. Cl. H01L 33/50; H01L 33/56; H01L 33/54

(52) U.S. Cl. CPC H01L 33/504; H01L 33/54; H01L 33/56

(57) ABSTRACT

A light emitting device package according to an embodiment may include: a body including first and second openings; a light emitting device disposed on the body and including first and second bonding parts; a first resin disposed between the body and the light emitting device; and a second resin disposed on a side surface and an upper surface of the light emitting device. According to an embodiment, the second resin may include functional groups detected in 800-850 wavenumber band, 929-1229 wavenumber band, and 1420-1605 wavenumber band, respectively, through FT-IR analysis, and [an area integral value of 800˜850 wavenumber band]/[an area integral value of 929˜1229 wavenumber band] may be in a range of 2% to 3%, and [the area integral value of 800˜850 wavenumber band]/[an area integral value of 1420˜1605 wavenumber band] may be provided in a range of 70% to 90%.

### TECHNICAL FIELD

Embodiments relate to a semiconductor device package, a method of manufacturing a semiconductor device package, and a light source device.

A semiconductor device comprising compounds such as GaN and AlGaN has many merits such as wide and easily adjustable bandgap energy, so the device can be used variously as light emitting devices, light receiving devices and various kinds of diodes.

In particular, light emitting devices such as light emitting diodes and laser diodes obtained by using a group III-V or a group II-VI compound semiconductor substances can implement light having various wavelength band such as red, green, blue and ultraviolet rays due to the development of thin film growth technology and device materials. In addition, the light emitting devices such as light emitting diodes and laser diodes obtained by using a group III-V or a group II-VI compound semiconductor substances can implement a white light source having high efficiency by using fluorescent substances or combining colors. Such a semiconductor device has advantages such as low power consumption, semi-permanent lifetime, quick response speed, safety, and environmental friendliness compared to conventional light sources such as fluorescent lamps and incandescent lamps.

In addition, when a light receiving device such as a photodetector or a solar cell is manufactured using a group III-V or a group II-VI compound semiconductor substances, a photoelectric current is generated by absorbing light having various wavelength domains with the development of device materials, so that light having various wavelength domains such as from gamma rays to radio waves can be used. In addition, the above light receiving device has advantages such as quick response speed, safety, environmental friendliness and easy control of device materials, so that the light receiving device can be easily used for a power control, a super-high frequency circuit or a communication module.

Accordingly, the semiconductor device has been applied and expanded to a transmission module of an optical communication means, a light emitting diode backlight replacing a cold cathode fluorescence lamp (CCFL) constituting a backlight of a liquid crystal display (LCD), a white light emitting diode lighting apparatus replaceable with a fluorescent lamp or an incandescent bulb, a vehicular headlight, a traffic light and a sensor for detecting gas or fire. In addition, the applications of the semiconductor device can be expanded to a high frequency application circuit, a power control apparatus, or a communication module.

For example, the light emitting device may be provided as a p-n junction diode having a characteristic in which electrical energy is converted into light energy by using a group III-V element or a group II-VI element in the periodic table, and various wavelengths can be realized by adjusting the composition ratio of the compound semiconductor substances.

For instance, a nitride semiconductor represents superior thermal stability and wide band gap energy so that the nitride semiconductor has been spotlighted in the field of optical devices and high-power electronic devices. In particular, blue, green, and UV light emitting devices employing the nitride semiconductor have already been commercialized and extensively used.

For example, an ultraviolet light emitting device may be used as a light emitting diode that emits light distributed in a wavelength range of 200 nm to 400 nm, used for sterilization and purification in the case of a short wavelength in the wavelength band, and used for an exposure machine, a curing machine, or the like in the case of a long wavelength.

Ultraviolet rays may be divided into three groups of UV-A (315 nm to 400 nm), UV-B (280 nm to 315 nm) and UV-C (200 nm to 280 nm) in the order of long wavelength. The UV-A (315 nm to 400 nm) has been applied to various fields such as UV curing for industrial use, curing of printing ink, an exposure machine, discrimination of counterfeit, photocatalytic disinfection, special illumination (aquarium/agriculture and the like), the UV-B (280 nm to 315 nm) has been used for medical use, and the UV-C (200 nm to 280 nm) has been applied to air purification, water purification, sterilization products, and the like.

Meanwhile, as a semiconductor device capable of providing a high output has been requested, a semiconductor device capable of increasing an output by applying high power source has been studied.

In addition, research on a method of improving the light extraction efficiency of a semiconductor device and enhancing the luminous intensity in a package stage in a semiconductor device package has been studied. Further, in the semiconductor device package, studies on a method of enhancing the bonding strength between the package electrode and the semiconductor device have been performed.

In addition, research on a method of reducing the manufacturing cost and improving the manufacturing yield by improving the process efficiency and changing the structure in a semiconductor device package has been studied.

### DETAIL DESCRIPTION OF THE INVENTION

### Technical Problem

Embodiments can provide a semiconductor device package, a method of manufacturing a semiconductor device package, and a light source device, that are capable of improving light extraction efficiency and electrical characteristics.

Embodiments can provide a semiconductor device package, a method of manufacturing a semiconductor device package, and a light source device, that are capable of reducing manufacturing cost and improving manufacturing yield by improving process efficiency and providing new package structure.

Embodiments can provide a semiconductor device package and a method of manufacturing a semiconductor device package that are capable of preventing a re-melting phenomenon from occurring in a bonding region of a semiconductor device package in a process of re-bonding the semiconductor device package to a board or the like.

### Technical Solution

A light emitting device package according to an embodiment may comprise a body comprising first and second openings; a light emitting device disposed on the body and comprising first and second bonding parts; a first resin disposed between the body and the light emitting device; and a second resin disposed on a side surface and an upper surface of the light emitting device, wherein the second resin may comprise functional groups detected in 800-850 wavenumber band, 929-1229 wavenumber band, and 1420-1605 wavenumber band, respectively, through FT-IR analysis, and wherein [an area integral value of 800˜850 wavenumber band]/[an area integral value of 929˜1229 wavenumber band] may be in a range of 2% to 3%, and [the area integral value of 800˜850 wavenumber band]/[an area integral value of 1420˜1605 wavenumber band] may be provided in a range of 70% to 90%.

According to an embodiment, the first resin may be disposed around the first and second bonding parts.

According to an embodiment, it may comprise a recess provided on an upper surface of the body and disposed overlapped with the light emitting device, when viewed above the light emitting device.

According to an embodiment, the recess may be provided at periphery of the first and second bonding parts.

According to an embodiment, it may comprise a recess provided on an upper surface of the body and provided around the light emitting device to be overlapped with the second resin, when viewed above the light emitting device.

According to an embodiment, the second resin may be provided in the recess.

According to an embodiment, lower surfaces of the first and second bonding parts may be disposed lower than upper surfaces of the first and second openings.

According to an embodiment, in may comprise a third resin disposed on an upper and a side surface of the second resin.

A light emitting device package according to an embodiment may comprise a conductor provided in the first and second openings and electrically connected with the first and second bonding parts, respectively.

A light emitting device package according to an embodiment may comprise a body comprising first and second openings; a light emitting device disposed on the body, and comprising a first bonding part disposed overlapped with the first opening in a vertical direction and a second bonding part disposed overlapped with the second opening in the vertical direction; and a resin disposed on the body, and disposed on a side surface and an upper surface of the light emitting device, wherein a boundary region in which an upper surface and a side surface of the resin are in contact with each other is provided in a curved shape, wherein the resin may comprise functional groups detected in 800-850 wavenumber band, 929-1229 wavenumber band, and 1420-1605 wavenumber band, respectively, through FT-IR analysis, and wherein [an area integral value of 800˜850 wavenumber band]/[an area integral value of 929˜1229 wavenumber band] may be in a range of 2% to 3%, and [the area integral value of 800˜850 wavenumber band]/[an area integral value of 1420˜1605 wavenumber band] may be provided in a range of 70% to 90%.

### Advantageous Effects

According to the semiconductor device package and the method of manufacturing the semiconductor device package of the embodiments, there is an advantage that light extraction efficiency, electrical characteristics and reliability can be improved.

According to the semiconductor device package and the method of manufacturing the semiconductor device package of the embodiments, there is an advantage that manufacturing cost can be reduced and manufacturing yield can be improved by improving process efficiency and providing new package structure.

The semiconductor device package according to the embodiment has an advantage that the reflector can be prevented from being discolored by providing the body with high reflectance, thereby improving the reliability of the semiconductor device package.

According to the semiconductor device package and the method of manufacturing the semiconductor device of the embodiments, there is an advantage that re-melting phenomenon can be prevented from occurring in the bonding region of the semiconductor device package in the process of re-bonding the semiconductor device package to a board or the like.

### DESCRIPTION OF DRAWINGS

FIG. 1 is a view showing a light emitting device package according to an embodiment of the present invention.

FIG. 2 is an exploded perspective view showing a light emitting device package according to an embodiment of the present invention.

FIG. 3 is a view showing another example of a light emitting device package according to an embodiment of the present invention.

FIG. 4 is a view showing another example of a light emitting device package according to an embodiment of the present invention.

FIG. 5 is a view showing another example of a light emitting device package according to an embodiment of the present invention.

FIG. 6 is a view showing another example of a light emitting device package according to an embodiment of the present invention.

FIG. 7 is a view showing another example of a light emitting device package according to an embodiment of the present invention.

FIGS. 8a and 8b are views explaining the difference between CH₃ functional group detection graphs of a resin applied to a light emitting device package according to an embodiment of the present invention and a conventional resin.

FIGS. 9a and 9b are views explaining the difference between Si—O—Si functional group detection graphs of a resin applied to a light emitting device package according to an embodiment of the present invention and a conventional resin.

FIGS. 10a and 10b are views explaining the difference between phenyl functional group detection graphs of a resin applied to a light emitting device package according to an embodiment of the present invention and a conventional resin.

### MODE FOR INVENTION

Hereinafter, an embodiment will be described with reference to accompanying drawings. In the description of the embodiments, it will be understood that, when a layer (or film), a region, a pattern, or a structure is referred to as being “on” or “under” another substrate, another layer (or film), another region, another pad, or another pattern, it can be “directly” or “indirectly” over the other substrate, layer (or film), region, pad, or pattern, or one or more intervening layers may also be present. Such a position of the layer has been described with reference to the drawings, but the embodiments are not limited thereto.

Hereinafter, a semiconductor device package and a method of manufacturing a semiconductor device package according to an embodiment of the present invention will be described in detail with reference to the accompanying drawings. Hereinafter, a case where a light emitting device is applied as an example of a semiconductor device will be described.

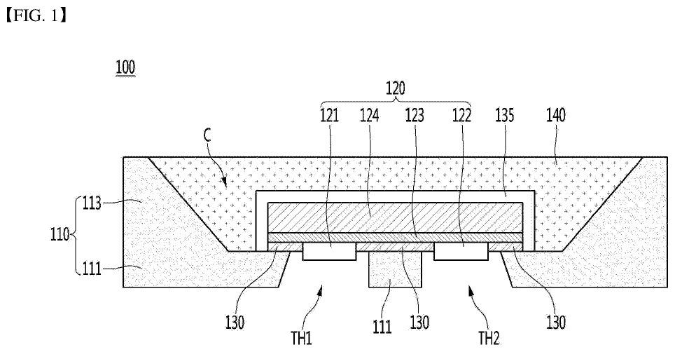

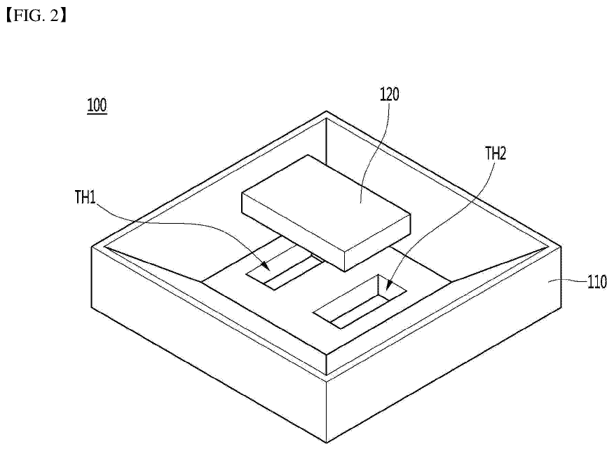

First, a light emitting device package according to an embodiment of the present invention will be described with reference to FIGS. 1 and 2.

FIG. 1 is a view showing a light emitting device package according to an embodiment of the present invention, and FIG. 2 is an exploded perspective view explaining the light emitting device package according to the embodiment shown in FIG. 1.

The light emitting device package 100 according to the embodiment may comprise a body 110 and a light emitting device 120, as shown in FIGS. 1 and 2.

FIG. 1 is a cross-sectional view of the light emitting device package 100 according to the embodiment of the present invention, and FIG. 2 illustrates a state before the light emitting device 120 is bonded to the body 110 to show the shape and arrangement relationship of the body 110 and the light emitting device 120.

The body 110 may comprise a first body 111 and a second body 113. The second body 113 may be disposed on the first body 111. The second body 113 may be disposed around an upper surface of the first body 111. The second body 113 may provide a cavity C on the upper surface of the first body 111.

In other words, the first body 111 may be referred to as a lower body, and the second body 113 may be referred to as an upper body.

The second body 113 may reflect upward light emitted from the light emitting device 120. The second body 113 may be disposed inclined with respect to the upper surface of the first body 111.

The body 110 may comprise the cavity C. The cavity may comprise a bottom surface and a side surface inclined to an upper surface of the body 110 at the bottom surface.

For example, the body 110 may be formed of at least one material selected from a group including polyphthalamide (PPA), polychloro tri phenyl (PCT), liquid crystal polymer (LCP), polyamide 9T (PA9T), silicone, epoxy molding compound (EMC), silicone molding compound (SMC), ceramics, photo sensitive glass (PSG), sapphire (Al₂O₃), and the like. In addition, the body 110 may comprise a high refractive index filler such as TiO₂ and SiO₂.

According to an embodiment, the light emitting device 120 may comprise a first bonding part 121, a second bonding part 122, a light emitting structure 123, and a substrate 124.

The light emitting structure 123 may comprise a first conductivity type semiconductor layer, a second conductivity type semiconductor layer, and an active layer disposed between the first conductivity type semiconductor layer and the second conductivity type semiconductor layer. The first bonding part 121 may be electrically connected to the first conductivity type semiconductor layer. In addition, the second bonding part 122 may be electrically connected to the second conductivity type semiconductor layer.

The light emitting device 120 may be disposed on the body 110. The light emitting device 120 may be disposed on the first body 111. The light emitting device 120 may be disposed in the cavity C provided by the second body 113.

The first bonding part 121 may be disposed on a lower surface of the light emitting device 120. The second bonding part 122 may be disposed on the lower surface of the light emitting device 120. The first bonding part 121 and the second bonding part 122 may be disposed spaced apart from each other on the lower surface of the light emitting device 120.

The first bonding part 121 may be disposed between the light emitting structure 123 and the first body 111. The second bonding part 122 may be disposed between the light emitting structure 123 and the first body 111.

Each of the first bonding part 121 and the second bonding part 122 may be provided as a single layer or a multilayer by using one or more materials selected from a group including Ti, Al, Sn, In, Ir, Ta, Pd, Co, Cr, Mg, Zn, Ni, Si, Ge, Ag, Ag alloy, Au, Hf, Pt, Ru, Rh, ZnO, IrOₓ, RuOₓ, NiO, RuOₓ/ITO, Ni/IrOₓ/Au, and Ni/IrOₓ/Au/ITO, or an alloy thereof.

The light emitting device package 100 according to the embodiment may comprise a first opening TH1 and a second opening TH2, as shown in FIGS. 1 and 2.

The body 110 may comprise the first opening TH1 passing through the lower surface of the body 110 on the bottom surface of the cavity C. The body 110 may comprise the second opening TH2 passing through the lower surface of the body 110 on the bottom surface of the cavity C.

The first opening TH1 may be provided in the first body 111. The first opening TH1 may be provided passing through the first body 111. The first opening TH1 may be provided passing through the upper surface and the lower surface of the first body 111 in a first direction.

The first opening TH1 may be disposed under the light emitting device 120. The first opening TH1 may be provided to overlap with the first bonding part 121 of the light emitting device 120. The first opening TH1 may be provided to overlap with the first bonding part 121 of the light emitting device 120 in a first direction toward the lower surface from the upper surface of the first body 111.

For example, the lower surface of the first bonding part 121 may be disposed lower than the upper surface of the first opening TH1. The lower surface of the first bonding part 121 may be disposed lower than the upper surface of the first body 111.

The second opening TH2 may be provided in the first body 111. The second opening TH2 may be provided passing through the first body 111. The second opening TH2 may be provided passing through the upper surface and the lower surface of the first body 111 in a first direction.

The second opening TH2 may be disposed under the light emitting device 120. The second opening TH2 may be provided to overlap with the second bonding part 122 of the light emitting device 120. The second opening TH2 may be provided to overlap with the second bonding part 122 of the light emitting device 120 in a first direction toward the lower surface from the upper surface of the first body 111.

For example, the lower surface of the second bonding part 122 may be disposed lower than the upper surface of the second opening TH2. The lower surface of the second bonding part 122 may be disposed lower than the upper surface of the first body 111.

The first opening TH1 and the second opening TH2 may be spaced apart from each other.

The first opening TH1 and the second opening TH2 may be spaced apart from each other under the lower surface of the light emitting device 120.

According to an embodiment, the width of the upper region of the first opening TH1 may be provided greater than the width of the lower surface of the first bonding part 121. In addition, the width of the upper region of the second opening TH2 may be provided greater than the width of the lower surface of the second bonding part 122. A lower region of the first and second bonding parts 121 and 122 may be inserted and disposed in the first and second openings TH1 and TH2.

In addition, the width of the upper region of the first opening TH1 may be provided smaller than or equal to the width of the lower region of the first opening TH1. Also, the width of the upper region of the second opening TH2 may be provided smaller than or equal to the width of the lower region of the second opening TH2.

The first opening TH1 may be provided in an inclined shape in which the width gradually decreases from the lower region to the upper region. The second opening TH2 may be provided in an inclined shape in which the width gradually decreases from the lower region to the upper region.

However, it is not limited thereto, and the inclined surfaces between the upper and lower regions of the first and second openings TH1 and TH2 may have a plurality of inclined surfaces having different slopes, and the inclined surfaces may be arranged with a curvature.

The width between the first opening TH1 and the second opening TH2 in the lower surface region of the first body 111 may be provided several hundred micrometers. For example, the width between the first opening TH1 and the second opening TH2 in the lower surface region of the first body 111 may be provided in a range of 100 micrometers to 150 micrometers.

The width between the first opening TH1 and the second opening TH2 in the lower surface region of the first body 111 may be set to be provided greater than a certain distance in order to prevent a short from being generated between the bonding pads in a case the light emitting device package 100 of the embodiment is later mounted on a circuit board, a sub mount, and the like.

The light emitting device package 100 according to the embodiment may comprise a first resin 130, as shown in FIG. 1.

The first resin 130 may be disposed between the light emitting device 120 and the first body 111. The first resin 130 may be disposed between the first bonding part 121 and the second bonding part 122. For example, the first resin 130 may be disposed in contact with a side surface of the first bonding part 121 and a side surface of the second bonding part 122.

The first resin 130 may provide a stable fixing force between the light emitting device 120 and the first body 111. The first resin 130 may be disposed in direct contact with the upper surface of the first body 111, for example. In addition, the first resin 130 may be disposed in direct contact with the lower surface of the light emitting device 120.

For example, the first resin 130 may comprise at least one of an epoxy-based material, a silicone-based material, and a hybrid material comprising an epoxy-based material and a silicone-based material. The first resin 130 may be referred to as an adhesive.

The first resin 130 may provide a stable fixing force between the first body 111 and the light emitting device 120, and may provide a light diffusion function between the light emitting device and the body when light is emitted through the lower surface of the light emitting device 120. When the light is emitted from the light emitting device 120 through the lower surface of the light emitting device 120, the first resin 130 provides a light diffusion function to improve the light extraction efficiency of the light emitting device package 100.

According to an embodiment, the first resin 130 may be provided in a portion of the body 110 in which the first and second openings TH1 and TH2 are provided. For example, the first resin 130 may be provided on a portion of the upper surface of the first body 111 through a method such as coating, dotting, or injection.

Next, the light emitting device 120 may be attached on the first body 111. Accordingly, the first resin 130 can be diffused and moved between the light emitting device 120 and the first body 111. The first resin 130 may be diffused and provided at periphery of the first and second bonding parts 121 and 122. The first resin 130 may be disposed between the first and second bonding parts 121 and 122 and the first and second openings TH1 and TH2. In addition, the first resin 130 can be controlled not to move into the first and second openings TH1 and TH2 by using viscosity, surface tension, and the like.

The first resin 130 may seal the upper region of the first and second openings TH1 and TH2. Accordingly, it is possible to prevent moisture or foreign matter from flowing into the region where the light emitting device 120 is disposed from the first and second openings TH1 and TH2.

Although not shown in FIGS. 1 and 2, the light emitting device package 100 according to an embodiment may comprise a recess provided on the upper surface of the first body 111. For example, the recess may be recessed from the bottom surface of the cavity C to the lower surface of the body 110.

The recess may be provided between the first and second bonding parts 121 and 122 when viewed from above the light emitting device 120. In addition, the recess may be provided around the first bonding part 121 and around the second bonding part 122.

The recess may provide a proper space in which a kind of underfill process can be performed under the light emitting device 120. The recess may be provided at a first depth or more to allow the first resin 130 to be sufficiently provided between the lower surface of the light emitting device 120 and the upper surface of the first body 111. In addition, the recess may be provided at a second depth or less to provide a stable strength of the first body 111.

For example, the depth T1 of the recess R may be provided of several tens of micrometers. The depth T1 of the recess R may be provided in a range of 40 micrometers to 60 micrometers.

When the recess is provided on the upper surface of the first body 110, the first resin 130 may be injected into the recess. Accordingly, the injection region and the injection amount of the first resin 130 can be easily controlled.

In addition, the light emitting device package 100 according to an embodiment may comprise a second resin 135 as shown in FIG. 1.

The second resin 135 may be disposed on a side surface of the light emitting device 120. The second resin 135 may be disposed on the upper surface of the light emitting device 120. The lower surface of the second resin 135 may be disposed in direct contact with the upper surface of the body 110. The lower surface of the second resin 135 may be disposed in direct contact with the upper surface of the first body 111.

The second resin 135 may seal the light emitting device 120. The side portion and the upper portion of the second resin 135 may be disposed in direct contact with the side surface and the upper surface of the light emitting device 120, respectively. In addition, the inner surface of the second resin 135 may be disposed in direct contact with the first resin 130. The lower surface of the upper portion of the second resin 135 may be disposed in direct contact with the upper surface of the light emitting device 120.

The second resin 135 may comprise a silicone-based resin.

In the case of conventional silicone-based resins, there are many cross linkers which are coupling between hydrogen H and carbon C, and there is a problem that heat resistance and light resistance are poor due to excessive cross linkers.

The second resin 135 according to an embodiment comprises a new silicone-based resin having a reduced number of cross linkers to overcome above disadvantage. The characteristics of the second resin 135 will be described later in more detail.

In addition, the second resin 135 may comprise a phosphor. The second resin 135 may comprise at least one of phosphors including a green phosphor, a red phosphor, and a yellow phosphor. For example, the second resin 135 may comprise a KSF (K₂SiF₆: Mn⁴) phosphor as a red phosphor.

According to an embodiment, the second resin 135 in a form of a film can be formed by mixing a liquid silicone binder and a phosphor. The second resin 135 formed in the form of a film may be provided on side surfaces and an upper surface of the light emitting device 120 to seal the periphery of the light emitting device 120.

The second resin 135 may be provided around the light emitting device 120 in the form of a film containing a phosphor to easily seal the periphery of the light emitting device 120 and light provided from the light emitting device 120 can be transmitted through the second resin 135 so that the light conversion efficiency can be improved.

The thickness of the second resin 135 may be provided of several hundred micrometers. For example, the thickness of the second resin 135 may be provided in a range of 150 micrometers to 300 micrometers.

The thickness of the second resin 135 may be selected to be 150 micrometers or more in consideration of the light conversion efficiency. In addition, the thickness of the second resin 135 may be selected to be 300 micrometers or less in consideration of process conditions such as the time required to volatilize the solvent used in the manufacturing process of the film.

In addition, the light emitting device package 100 according to an embodiment may comprise a third resin 140, as shown in FIG. 1.

The third resin 140 may be provided on the light emitting device 120. The third resin 140 may be disposed on the first body 111. The third resin 140 may be disposed in the cavity C provided by the second body 113. The third resin 140 may be disposed on the second resin 135.

The third resin 140 may comprise an insulating material. The third resin 140 may be provided as a clear molding member. For example, the third resin 140 may comprise a silicone-based resin or an epoxy-based resin.

In addition, the third resin 140 may comprise wavelength conversion means for receiving light emitted from the light emitting device 120 and providing wavelength-converted light. For example, the third resin 140 may comprise a phosphor, a quantum dot, and the like.

In addition, according to an embodiment, the light emitting structure 123 may be provided as a compound semiconductor. The light emitting structure 123 may be provided as, for example, Group II-VI or Group III-V compound semiconductors. For example, the light emitting structure 123 may comprise at least two elements selected from aluminum (Al), gallium (Ga), indium (In), phosphorus (P), arsenic (As), and nitrogen (N).

The light emitting structure 123 may comprise a first conductivity type semiconductor layer, an active layer, and a second conductivity type semiconductor layer.

The first and second conductivity type semiconductor layers may be implemented as at least one of Group III-V or Group II-VI compound semiconductors. For example, each of the first and second conductivity type semiconductor layers may comprise a semiconductor material having a compositional formula of InₓAl_{y}Ga_{1-x-y}N (0≤x≤1, 0≤y≤1, 0≤x+y≤1). For example, each of the first and second conductivity type semiconductor layers may comprise at least one selected from a group including GaN, AlN, AlGaN, InGaN, InN, InAlGaN, AlInN, AlGaAs, GaP, GaAs, GaAsP, AlGaInP, and the like. The first conductivity type semiconductor layer may be an n-type semiconductor layer that is doped with an N-type dopant such as Si, Ge, Sn, Se, Te, and the like.

The second conductivity type semiconductor layer may be a p-type semiconductor layer that is doped with a p-type dopant such as Mg, Zn, Ca, Sr, Ba, and the like.

The active layer may be formed of a compound semiconductor. For example, the active layer may be formed of at least one of Group III-V or Groups II-VI compound semiconductors. When the active layer has a multi-well structure, the active layer may comprise a plurality of well layers and a plurality of barrier layers, which are alternately arranged and may be formed of a material having a compositional formula of InₓAl_{y}Ga_{1-x-y}N (0≤x≤1, 0≤y≤1). For example, the active layer may comprise at least one selected from a group including InGaN/GaN, GaN/AlGaN, AlGaN/AlGaN, InGaN/AlGaN, InGaN/InGaN, AlGaAs/GaAs, InGaAs/GaAs, InGaP/GaP, AlInGaP/InGaP, InP/GaAs, and the like.

The light emitting device package 100 according to an embodiment may be supplied in a state where the first and second openings TH1 and TH2 are empty. Then, in the process of mounting the light emitting device package 100 on a submount, a main board or the like, a conductor may be formed in the first and second openings TH1 and TH2.

In the light emitting device package 100 of an embodiment, by considering that a conductor may be provided later in the first and second openings TH1 and TH2, the thickness of the first body 111 may be selected to be in a range of several tens of micrometers to several hundreds of micrometers.

For example, in consideration of the strength of the body 110, the thickness of the first body 111 may be selected to be greater than or equal to 70 micrometers. In addition, the thickness of the first body 111 may be selected to be smaller than or equal to 110 micrometers so that the conductor can be easily supplied to the first and second openings TH1 and TH2.

In addition, according to the light emitting device package 100 of another embodiment, it may be supplied in a state where conductors are provided in the first and second openings TH1 and TH2.

In the light emitting device package 100 according to the embodiment, power may be supplied to the first bonding part 121 through a conductor provided in the first opening TH1, and power may be supplied to the second bonding part 122 through a conductor provided in the second opening TH2.

Accordingly, the light emitting device 120 can be driven by the driving power supplied through the first bonding part 121 and the second bonding part 122. The light emitted from the light emitting device 120 may be provided in an upward direction of the body 110.

Meanwhile, the light emitting device package 100 according to the embodiment described above may be mounted on a submount, a circuit board, or the like, and may be supplied.

However, when the light emitting device package is mounted on a submount or a circuit board, a high temperature process such as a reflow process or the like may be applied. Here, in the reflow process, a re-melting phenomenon occurs in a bonding region between the lead frame and the light emitting device provided in the light emitting device package, so that the stability of the electrical connection and the physical coupling may be weakened.

However, according to the light emitting device package and the method of manufacturing the light emitting device package of the embodiment, the first bonding part 121 and the second bonding part 122 of the light emitting device 120 according to the embodiment can receive the driving power through the conductors. The melting point of the conductors can be selected to have a higher value than the melting point of the common bonding material.

Therefore, even when the light emitting device package 100 according to the embodiment is bonded to a main board through a reflow process, re-melting phenomenon does not occur, so there are advantages that electrical connection and physical bonding force are not deteriorated.

In addition, according to the light emitting device package 100 and the method of manufacturing the light emitting device package of the embodiment, a conductive paste can be applied as a conductor, and the body 110 does not need to be exposed to high temperatures in the process of manufacturing the light emitting device package. Therefore, according to the embodiment, it is possible to prevent the body 110 from being exposed to high temperatures and being damaged or discolored.

Accordingly, the selection range for the material constituting the body 110 can be widened. According to the embodiment, the body 110 may be provided using not only expensive materials such as ceramics but also relatively inexpensive resin materials.

For example, the body 110 may comprise at least one material selected from a group including PolyPhtalAmide (PPA) resin, PolyCyclohexylenedimethylene Terephthalate (PCT) resin, Epoxy Molding Compound (EMC) resin, and Silicone Molding Compound (SMC) resin.

Meanwhile, according to the light emitting device package of the embodiment described above, the body 110 may comprise only a support member having a flat upper surface and may not be provided with inclined reflection parts.

In other words, according to the light emitting device package of the embodiment, the body 110 may be provided with a structure for providing the cavity C. In addition, the body 110 may be provided with a flat upper surface without providing the cavity C.

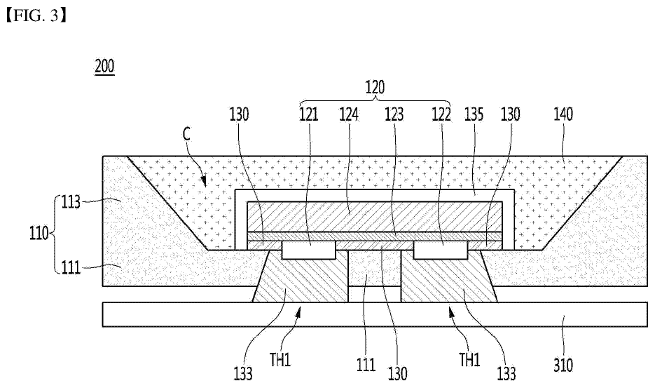

Next, referring to FIG. 3, another example of the light emitting device package according to an embodiment will be described. FIG. 3 is a view showing another example of a light emitting device package according to an embodiment of the present invention.

In describing the light emitting device package of the embodiment with reference to FIG. 3, descriptions overlapping with those described with reference to FIGS. 1 and 2 may be omitted.

The light emitting device package 200 according to the embodiment of the present invention shown in FIG. 3 is an example in which the light emitting device package 100 described with reference to FIGS. 1 and 2 is mounted on a circuit board 310 and supplied.

The light emitting device package 200 according to the embodiment may comprise a circuit board 310, a body 110, and a light emitting device 120, as shown in FIG. 3.

The circuit board 310 may comprise a first pad, a second pad, and a board. A power supply circuit controlling driving of the light emitting device 120 may be provided on the board.

The body 110 may be disposed on the circuit board 310. The first pad region of the circuit board 310 and the first bonding part 121 may be electrically connected through the conductor 133.

In addition, the second pad region of the circuit board 310 and the second bonding part 122 may be electrically connected through the conductor 133.

The conductor 133 may be provided as a conductive adhesive, for example. The conductor 133 may be provided on the first and second pad regions of the circuit board 310, when the body 110 is mounted on the circuit board 310, the conductor 133 may be moved into the first and second openings TH1 and TH2 and may be provided in contact with the first and second bonding parts 121 and 122. For example, the conductor 133 may be diffused and moved into the first and second openings TH1 and TH2 through a capillary phenomenon or the like.

For example, the conductor 133 may comprise one material selected from a group including Ag, Au, Pt, Sn, Cu, and the like or an alloy thereof. However, it is not limited thereto, and the conductor 133 may be formed of a material capable of securing a conductive function.

For example, the conductor 133 may be formed using a conductive paste. The conductive paste may comprise a solder paste, a silver paste, or the like, and may be composed of a multi-layer of different materials, or a multi-layer or a single layer of an alloy. For example, the conductor 133 may comprise a SAC (Sn—Ag—Cu) material.

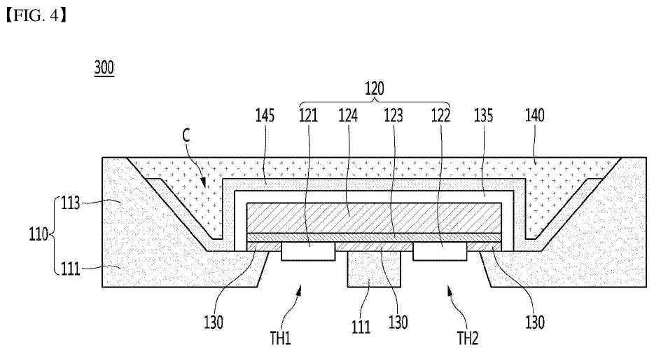

Next, referring to FIG. 4, another example of the light emitting device package according to an embodiment will be described. FIG. 4 is a view showing another example of the light emitting device package according to an embodiment of the present invention.

In describing the light emitting device package of the embodiment with reference to FIG. 4, descriptions overlapping with those described with reference to FIGS. 1 to 3 may be omitted.

The light emitting device package 300 according to the embodiment may further comprise a fourth resin 145.

The fourth resin 145 may be disposed on the second resin 135. The fourth resin 145 may be disposed on a side surface of the second resin 135. The fourth resin 145 may extend from a side surface of the second resin 135 to an inclined surface of the second body 113. The fourth resin 145 may be disposed between the second resin 135 and the third resin 140.

The fourth resin 145 can provide a kind of double mold function and can improve the moisture absorption prevention of the light emitting device package. In addition, the fourth resin 145 can enhance the fixing force of the light emitting device 120.

For example, the fourth resin 145 may comprise at least one of a silicone-based resin and an epoxy-based resin. In addition, the fourth resin 145 may comprise a reflective material.

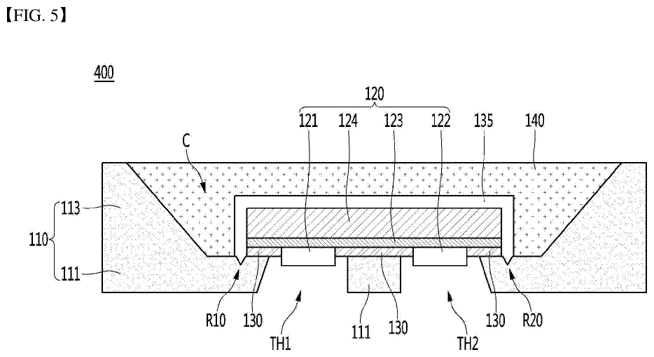

Next, referring to FIG. 5, another example of the light emitting device package according to an embodiment will be described. FIG. 5 is a view showing another example of the light emitting device package according to an embodiment of the present invention.

In describing a light emitting device package according to an embodiment with reference to FIG. 5, descriptions overlapping with those described with reference to FIGS. 1 to 4 may be omitted.

The light emitting device package 400 according to the embodiment may comprise a recess provided on an upper surface of the body 110.

For example, the recess may comprise a first recess R10 and a second recess R20 provided on the upper surface of the first body 111.

The first and second recesses R10 and R20 may be provided around the light emitting device 120 and overlapped with the second resin 135 when viewed from above the light emitting device 120. The second resin 135 may be disposed in the first and second recesses R10 and R20.

The coupling force between the second resin 135 and the first body 111 can be improved by the first and second recesses R10 and R20. In addition, as the moisture absorption path through which moisture or the like penetrates from the side region of the light emitting device package 400 to the light emitting device 120 is increased by the first and second recesses R10 and R20, the moisture absorption prevention effect can be improved.

In addition, according to another embodiment, the first and second recesses R10 and R20 may be provided in a state in which the second resin 135 is not completely filled, and a kind of an air void may exist.

The first and second recesses R10 and R20 may be provided in connection with each other.

In addition, the first recess R10 and the second recess R20 are not connected to each other, and the first recess R10 may be provided around the first opening TH1 and the second recess R20 may be provided around the second opening TH2.

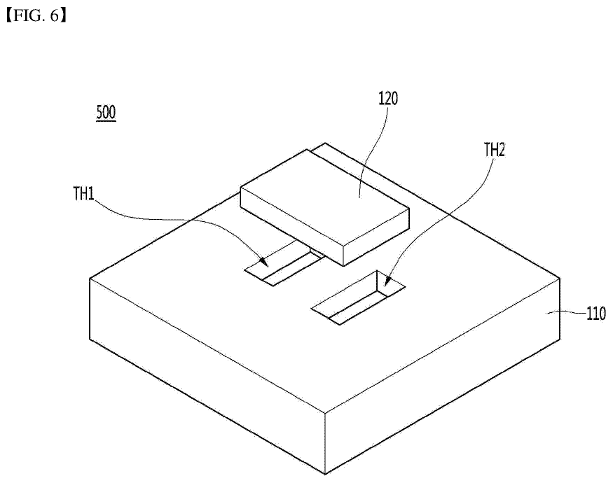

Next, referring to FIG. 6, another example of the light emitting device package according to an embodiment will be described. FIG. 6 is a view showing another example of the light emitting device package according to an embodiment of the present invention.

In describing a light emitting device package according to an embodiment with reference to FIG. 6, descriptions overlapping with those described with reference to FIGS. 1 to 5 may be omitted.

The light emitting device package according to the embodiment described above may comprise a body 110 provided with a first opening TH1 and a second opening TH2 as shown in FIG. 6. The upper surface of the body 110 may be provided flat, for example, over the entire area.

The first and second openings TH1 and TH2 may be provided passing through the body 110 in a first direction from the upper surface toward the lower surface.

The first and second openings TH1 and TH2 may be provided in a rectangular shape on the upper surface of the body 110, for example. In addition, the first and second openings TH1 and TH2 may be provided in a rectangular shape on the lower surface of the body 110.

In addition, according to another embodiment, the first and second openings TH1 and TH2 may be provided in a circular shape on the upper surface and the lower surface of the body 110, respectively. Further, the first opening TH1 may be provided as a plurality of openings, and the second opening TH2 may be provided as a plurality of openings.

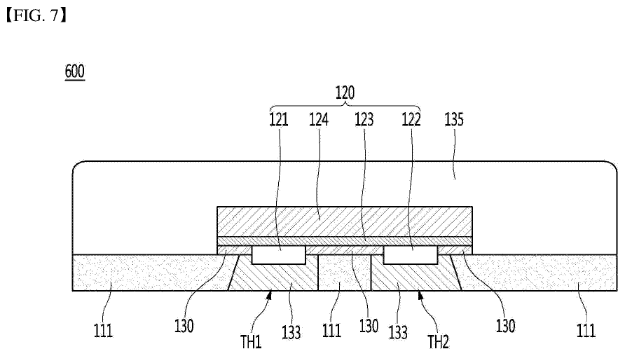

Next, referring to FIG. 7, another example of the light emitting device package according to an embodiment will be described. FIG. 7 is a view showing another example of the light emitting device package according to an embodiment of the present invention.

In describing a light emitting device package according to an embodiment, descriptions overlapping with those described with reference to FIGS. 1 to 6 may be omitted.

The light emitting device package 600 according to the embodiment may comprise a first body 111 and a light emitting device 120. The light emitting device 120 may be disposed on the first body 111.

For example, the first body 111 may be provided as a flat surface in the entire upper surface region as described with reference to FIG. 6.

According to the embodiment, the light emitting device 120 may comprise a first bonding part 121, a second bonding part 122, a light emitting structure 123, and a substrate 124.

The light emitting structure 123 may comprise a first conductivity type semiconductor layer, a second conductivity type semiconductor layer, and an active layer disposed between the first conductivity type semiconductor layer and the second conductivity type semiconductor layer. The first bonding part 121 may be electrically connected to the first conductivity type semiconductor layer. In addition, the second bonding part 122 may be electrically connected to the second conductivity type semiconductor layer.

The first bonding part 121 may be disposed on a lower surface of the light emitting device 120. The second bonding part 122 may be disposed on the lower surface of the light emitting device 120. The first bonding part 121 and the second bonding part 122 may be spaced apart from each other on the lower surface of the light emitting device 120.

The first bonding part 121 may be disposed between the light emitting structure 123 and the first body 111. The second bonding part 122 may be disposed between the light emitting structure 123 and the first body 111.

Each of the first bonding part 121 and the second bonding part 122 may be provided as a single layer or a multilayer by using one or more materials selected from a group including Ti, Al, Sn, In, Ir, Ta, Pd, Co, Cr, Mg, Zn, Ni, Si, Ge, Ag, Ag alloy, Au, Hf, Pt, Ru, Rh, ZnO, IrOₓ, RuOₓ, NiO, RuOₓ/ITO, Ni/IrOₓ/Au, and Ni/IrOₓ/Au/ITO, or an alloy thereof.

The light emitting device package 600 according to the embodiment may comprise a first opening TH1 and a second opening TH2.

The first body 111 may comprise the first opening TH1 passing through the lower surface from the upper surface. The first body 111 may comprise the second opening TH2 passing through the lower surface from the upper surface.

The first opening TH1 may be disposed under the light emitting device 120. The first opening TH1 may be provided to overlap with the first bonding part 121 of the light emitting device 120. The first opening TH1 may be provided to overlap with the first bonding part 121 of the light emitting device 120 in a first direction toward the lower surface from the upper surface of the first body 111.

For example, the lower surface of the first bonding part 121 may be disposed lower than the upper surface of the first opening TH1. The lower surface of the first bonding part 121 may be disposed lower than the upper surface of the first body 111.

The second opening TH2 may be disposed under the light emitting device 120. The second opening TH2 may be provided to overlap with the second bonding part 122 of the light emitting device 120. The second opening TH2 may be provided to overlap with the second bonding part 122 of the light emitting device 120 in a first direction toward the lower surface from the upper surface of the first body 111.

For example, the lower surface of the second bonding part 122 may be disposed lower than the upper surface of the second opening TH2. The lower surface of the second bonding part 122 may be disposed lower than the upper surface of the first body 111.

The first opening TH1 and the second opening TH2 may be spaced apart from each other.

The first opening TH1 and the second opening TH2 may be spaced apart from each other under the lower surface of the light emitting device 120.

According to an embodiment, the width of the upper region of the first opening TH1 may be provided greater than the width of the lower surface of the first bonding part 121. In addition, the width of the upper region of the second opening TH2 may be provided greater than the width of the lower surface of the second bonding part 122. A lower region of the first and second bonding parts 121 and 122 may be inserted and disposed in the first and second openings TH1 and TH2.

In addition, the width of the upper region of the first opening TH1 may be provided smaller than or equal to the width of the lower region of the first opening TH1. Also, the width of the upper region of the second opening TH2 may be provided smaller than or equal to the width of the lower region of the second opening TH2.

The first opening TH1 may be provided in an inclined shape in which the width gradually decreases from the lower region to the upper region. The second opening TH2 may be provided in an inclined shape in which the width gradually decreases from the lower region to the upper region.

However, it is not limited thereto, and the inclined surfaces between the upper and lower regions of the first and second openings TH1 and TH2 may have a plurality of inclined surfaces having different slopes, and the inclined surfaces may be arranged with a curvature.

The light emitting device package 600 according to the embodiment may comprise a first resin 130.

The first resin 130 may be disposed between the light emitting device 120 and the first body 111. The first resin 130 may be disposed between the first bonding part 121 and the second bonding part 122. For example, the first resin 130 may be disposed in contact with a side surface of the first bonding part 121 and a side surface of the second bonding part 122.

The first resin 130 may provide a stable fixing force between the light emitting device 120 and the first body 111. The first resin 130 may be disposed in direct contact with the upper surface of the first body 111, for example. In addition, the first resin 130 may be disposed in direct contact with the lower surface of the light emitting device 120.

For example, the first resin 130 may comprise at least one of an epoxy-based material, a silicone-based material, and a hybrid material comprising an epoxy-based material and a silicone-based material. The first resin 130 may be referred to as an adhesive.

The first resin 130 may provide a stable fixing force between the first body 111 and the light emitting device 120, and may provide a light diffusion function between the light emitting device and the body when light is emitted through the lower surface of the light emitting device 120. When the light is emitted from the light emitting device 120 through the lower surface of the light emitting device 120, the first resin 130 provides a light diffusion function to improve the light extraction efficiency of the light emitting device package 100.

According to an embodiment, the first resin 130 may be provided in a portion of the body 110 in which the first and second openings TH1 and TH2 are provided. For example, the first resin 130 may be provided on a portion of the upper surface of the first body 111 through a method such as coating, dotting, or injection.

Next, the light emitting device 120 may be attached on the first body 111. Accordingly, the first resin 130 can be diffused and moved between the light emitting device 120 and the first body 111. The first resin 130 may be diffused and provided at periphery of the first and second bonding parts 121 and 122. The first resin 130 may be disposed between the first and second bonding parts 121 and 122 and the first and second openings TH1 and TH2. In addition, the first resin 130 can be controlled not to move into the first and second openings TH1 and TH2 by using viscosity, surface tension, and the like.

The first resin 130 may seal the upper region of the first and second openings TH1 and TH2. Accordingly, it is possible to prevent moisture or foreign matter from flowing into the region where the light emitting device 120 is disposed from the first and second openings TH1 and TH2.

In addition, the light emitting device package 600 according to the embodiment may comprise a second resin 135.

The second resin 135 may be disposed on a side surface of the light emitting device 120.

The second resin 135 may be disposed on the upper surface of the light emitting device 120. The lower surface of the second resin 135 may be disposed in direct contact with the upper surface of the body 110. The lower surface of the second resin 135 may be disposed in direct contact with the upper surface of the first body 111.

The second resin 135 may seal the light emitting device 120. The side portion and the upper portion of the second resin 135 may be disposed in direct contact with the side surface and the upper surface of the light emitting device 120, respectively. In addition, the inner surface of the second resin 135 may be disposed in direct contact with the first resin 130. The lower surface of the upper portion of the second resin 135 may be disposed in direct contact with the upper surface of the light emitting device 120.

The side surface of the second resin 135 and the side surface of the first body 111 may be provided on the same plane.

For example, in the method of manufacturing the light emitting device package according to the embodiment, the second resin 135 may be provided on a plurality of first bodies 111 arranged in an array form. An individual light emitting device package 600 can be obtained through a cutting process of the first body 111 and the second resin 135.

Here, the cutting process for the first body 111 and the second resin 135 may be performed in a direction toward the upper surface from the lower surface of the first body 111. At this time, the cutting process may be cut to the upper surface of the second resin 135.

In addition, the cutting process is not completely performed to the upper surface of the second resin 135, and the cutting process is completed in a state in which some regions are not separated and are connected to each other, and then a separating process may be performed to separate the connected second resin 135. This is achieved by using the ductility characteristics of the second resin 135, and the upper surface corner portion of the second resin 135 can be provided in a rounded shape while contracting through the separation and curing process.

That is, a boundary region where the upper surface and side surfaces of the second resin 135 are in contact may be provided as a curved surface. As another expression, an edge region where the upper surface and side surfaces of the second resin 135 are in contact may be provided as a curved surface.

As described above, the degree of curvature in the edge region where the upper surface and the side surface of the second resin 135 contact each other can be adjusted through adjustment of the thickness in which the cutting process is not completely performed in the upper surface region of the second resin 135.

According to the embodiment, the corner regions where the upper surface and the side surfaces of the second resin 135 are in contact with each other are not provided in a vertical shape, but are provided in a curved shape, so that light extraction efficiency can be improved.

For example, the second resin 135 may comprise a silicone-based resin.

In the case of conventional silicone-based resins, there are many cross-linkers which are coupling between hydrogen H and carbon C, and there is a problem that heat resistance and light resistance are poor due to excessive cross linkers.

The second resin 135 according to an embodiment comprises a new silicone-based resin having a reduced number of cross linkers to overcome above disadvantage. The characteristics of the second resin 135 will be described later in more detail.

In addition, the second resin 135 may comprise a phosphor. The second resin 135 may comprise at least one of phosphors including a green phosphor, a red phosphor, and a yellow phosphor. For example, the second resin 135 may comprise a KSF (K₂SiF₆: Mn⁴) phosphor as a red phosphor.

According to an embodiment, the second resin 135 in a form of a film can be formed by mixing a liquid silicone binder and a phosphor. The second resin 135 formed in the form of a film may be provided on side surfaces and an upper surface of the light emitting device 120 to seal the periphery of the light emitting device 120.

The second resin 135 may be provided around the light emitting device 120 in the form of a film containing a phosphor to easily seal the periphery of the light emitting device 120 and light provided from the light emitting device 120 can be transmitted through the second resin 135 so that the light conversion efficiency can be improved.

The thickness of the second resin 135 may be provided of several hundred micrometers. For example, the thickness of the second resin 135 may be provided in a range of 150 micrometers to 300 micrometers.

The thickness of the second resin 135 may be selected to be 150 micrometers or more in consideration of the light conversion efficiency. In addition, the thickness of the second resin 135 may be selected to be 300 micrometers or less in consideration of process conditions such as the time required to volatilize the solvent used in the manufacturing process of the film.

The light emitting device package 600 according to the embodiment may comprise a conductor 133 disposed in the first and second openings TH1 and TH2.

The conductor 133 disposed in the first opening TH1 may be electrically connected to the first bonding part 121. The conductor 133 disposed in the second opening TH2 may be electrically connected to the second bonding part 122.

The conductor 133 may be provided as a conductive adhesive, for example.

For example, the conductor 133 may comprise one material selected from a group including Ag, Au, Pt, Sn, Cu, and the like or an alloy thereof. However, it is not limited thereto, and the conductor 133 may be formed of a material capable of securing a conductive function.

For example, the conductor 133 may be formed using a conductive paste. The conductive paste may comprise a solder paste, a silver paste, or the like, and may be composed of a multi-layer of different materials, or a multi-layer or a single layer of an alloy. For example, the conductor 133 may comprise a SAC (Sn—Ag—Cu) material.

Meanwhile, as described above, the light emitting device package 600 according to the embodiment can be supplied in a state where the first and second openings TH1 and TH2 are empty. Then, in the process of mounting the light emitting device package 600 on a submount, a main board or the like, a conductor may be formed in the first and second openings TH1 and TH2.

In the light emitting device package 600 of an embodiment, by considering that a conductor may be provided later in the first and second openings TH1 and TH2, the thickness of the first body 111 may be selected to be in a range of several tens of micrometers to several hundreds of micrometers.

For example, in consideration of the strength of the body 110, the thickness of the first body 111 may be selected to be greater than or equal to 70 micrometers. In addition, the thickness of the first body 111 may be selected to be smaller than or equal to 110 micrometers so that the conductor can be easily supplied to the first and second openings TH1 and TH2.

In the light emitting device package 600 according to the embodiment, power may be supplied to the first bonding part 121 through the conductor 133 provided in the first opening TH1 and power may be supplied to the second bonding part 122 through the conductor 133 provided in the second opening TH2. Accordingly, the light emitting device 120 can be driven by the driving power supplied through the first bonding part 121 and the second bonding part 122.

Meanwhile, the light emitting device package 600 according to the embodiment described above may be mounted on a submount, a circuit board, or the like, and may be supplied.

However, when the light emitting device package is mounted on a submount or a circuit board, a high temperature process such as a reflow process or the like may be applied. Here, in the reflow process, a re-melting phenomenon occurs in a bonding region between the lead frame and the light emitting device provided in the light emitting device package, so that the stability of the electrical connection and the physical coupling may be weakened.

However, according to the light emitting device package and the method of manufacturing the light emitting device package of the embodiment, the first bonding part 121 and the second bonding part 122 of the light emitting device 120 according to the embodiment can receive the driving power through the conductors. The melting point of the conductors can be selected to have a higher value than the melting point of the common bonding material.

Therefore, even when the light emitting device package 600 according to the embodiment is bonded to a main board through a reflow process, re-melting phenomenon does not occur, so there are advantages that electrical connection and physical bonding force are not deteriorated.

In addition, according to the light emitting device package 100 and the method of manufacturing the light emitting device package of the embodiment, a conductive paste can be applied as a conductor, and the first body 111 does not need to be exposed to high temperatures in the process of manufacturing the light emitting device package. Therefore, according to the embodiment, it is possible to prevent the first body 111 from being exposed to high temperatures and being damaged or discolored.

Accordingly, the selection range for the material constituting the first body 111 can be widened. According to the embodiment, the first body 111 may be provided using not only expensive materials such as ceramics but also relatively inexpensive resin materials.

For example, the body 110 may comprise at least one material selected from a group including PolyPhtalAmide (PPA) resin, PolyCyclohexylenedimethylene Terephthalate (PCT) resin, Epoxy Molding Compound (EMC) resin, and Silicone Molding Compound (SMC) resin.

Meanwhile, in the above description, the case where the side surface of the second resin 135 and the side surface of the first body 111 form the same plane has been described. However, according to another embodiment, the second resin 135 may be provided in a shape that wraps around the side surface of the first body 111. That is, the second resin 135 may be disposed on a side surface and an upper surface of the light emitting device 120, and may be disposed on a side surface of the first body 111.

Accordingly, the light conversion efficiency of light provided from the light emitting device 120 can be improved by the second resin 135, and the moisture absorption blocking effect on the light emitting device 120 can be improved by the second resin 135.

Next, characteristics of the second resin applied to the light emitting device package according to the embodiment of the present invention will be described in further detail.

Conventional silicone-based resins are vulnerable to heat resistance and light resistance due to the large number of cross linkers.

On the other hand, in the embodiments, the number of cross linkers was reduced, and a silicone-based resin excellent in heat resistance and light resistance was used. Such a silicone-based resin (hereinafter referred to as an improved silicone) may exist in a liquid form in which a silicone binder is dipped in a solvent. In addition, the improved silicone has excellent sticky characteristics and crack prevention properties.

Accordingly, the silicone-based resin applied to the light emitting device package according to the embodiment can effectively seal the light emitting device. In addition, the silicone-based resin applied to the light emitting device package according to the embodiment can be stable to thermal changes and can prevent crack from occurring in the light emitting device package.

Hereinafter, characteristics of the second resin applied to the light emitting device package according to the embodiment and the conventional resin detected by the FT-IR (Fourier Transformation-Infrared) equipment will be described.

FT-IR equipment is one of the basics of spectroscopic equipment and is a device that determines the presence or absence of most chemical functional groups, when infrared rays are irradiated on a sample, a part of the irradiated light is absorbed by the sample and appears as a specific peak, so that the characteristics of the corresponding sample can be identified through such a specific peak.

A specific peak is a peak that appears only in a specific functional group, and the position of a peak can be confirmed in a handbook.

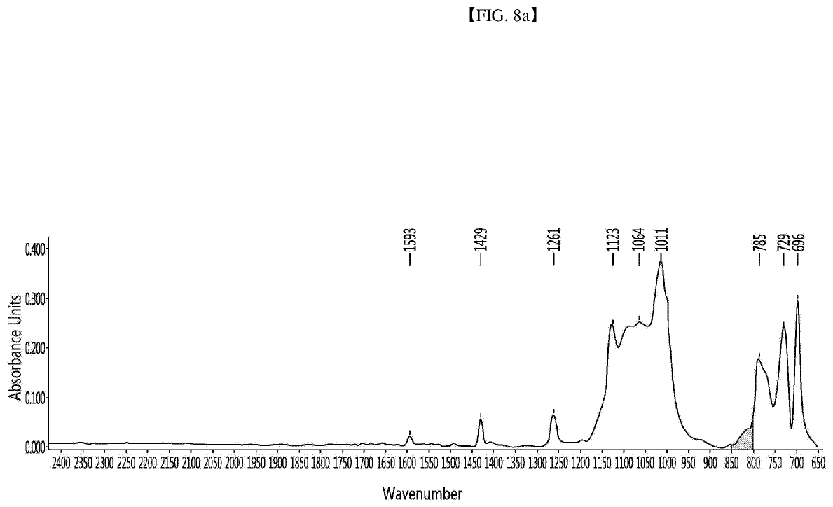

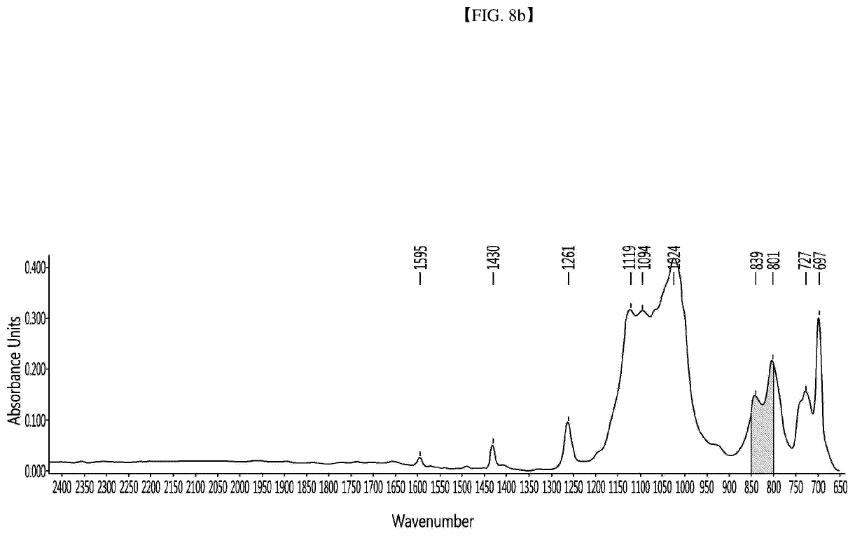

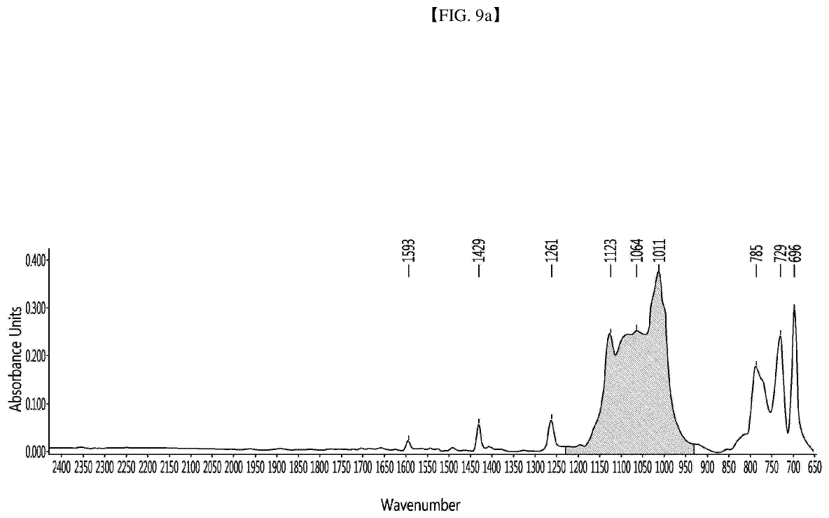

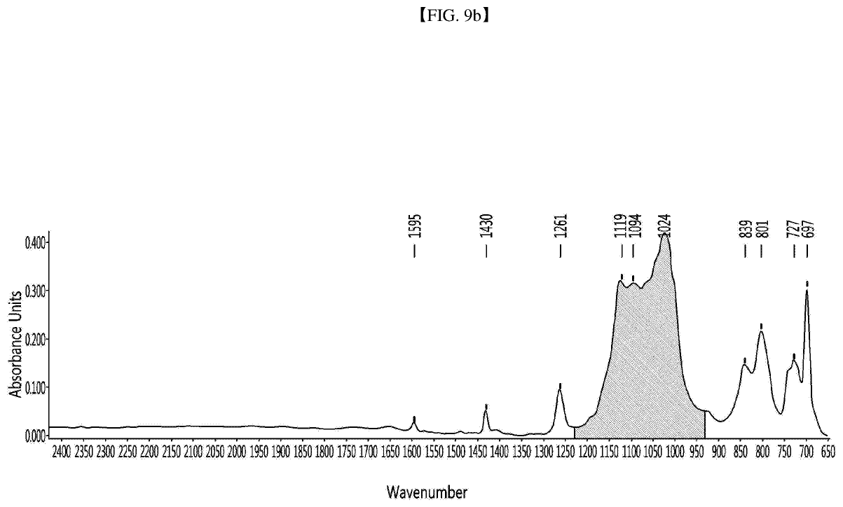

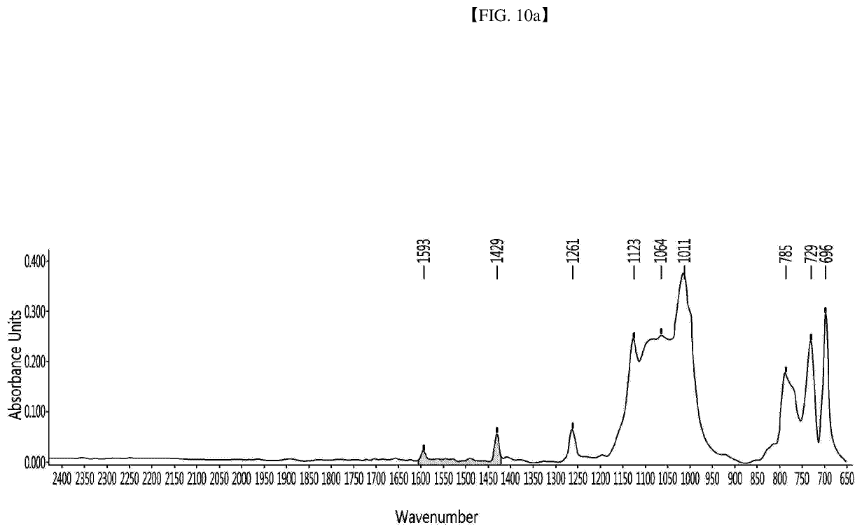

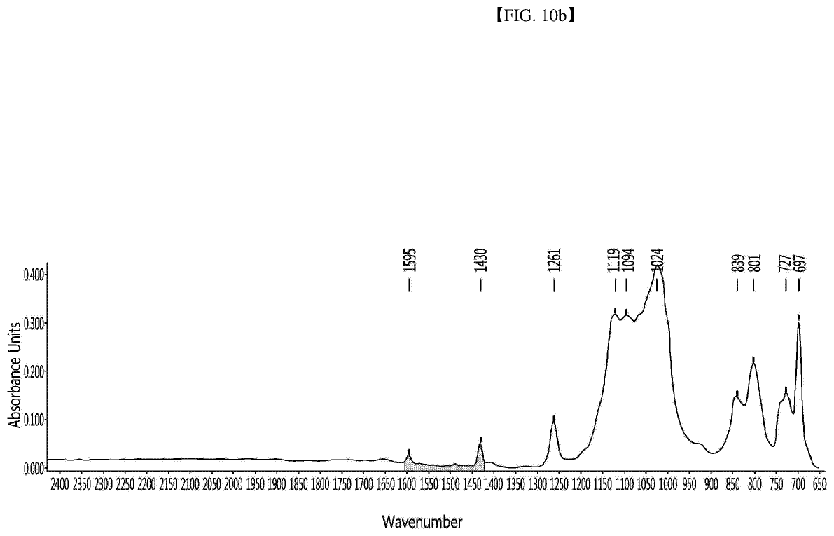

FIGS. 8a and 8b are views explaining the difference between the CH₃ functional group detection graphs of the second resin applied to the light emitting device package according to the embodiment of the present invention and the conventional resin, FIGS. 9a and 9b are views explaining the difference between the Si—O—Si functional graphs of the second resin applied to the light emitting device package according to the embodiment of the present invention and the conventional resin, and FIG. 10a and FIG. 10b are views explaining the difference between the phenyl functional group detection graphs of the resin applied to the light emitting device package according to the embodiment of the present invention and the conventional resin.

As shown in the figures, in both conventional silicone and improved silicone, a peak of phenyl functional group appears at 1450 cm⁻¹, and a peak of Si—O—Si functional group appears at 1260 cm⁻¹ and 1100-1000 cm⁻¹.

Meanwhile, the magnitude of the cross linker can be compared using FT-IR equipment.

For example, as shown in FIGS. 8a and 8b, 800-850 cm⁻¹ (hatched area) may be associated with the cross linker.

That is, the magnitude of the cross linker can be grasped by the integration result of the 800-850 cm⁻¹ region.

The integrated value for the 800-850 cm⁻¹ region shown in FIG. 8a can be calculated to be smaller than the integrated value for the 800-850 cm⁻¹ region shown in FIG. 8b.

As described above, the improved silicone has a reduced number of cross linkers, which not only has excellent heat resistance and light resistance, but also has excellent sticky characteristics and crack prevention properties.

Meanwhile, it can be confirmed that the second resin according to the embodiments and the conventional resin have the differences as shown in the following [Table 1].

TABLE 1

| | | Conventional | The second |
|---|---|---|---|
| Item | | resin | resin |
| Actual area | CH₃ (800 to 850 | 7.61 | 1.11 |
| integral | wavenumber band) | | |
| value | Si—O—Si (929 to | 90.62 | 44.67 |
| | 1229 wavenumber | | |
| | band) | | |
| | Phenyl (1420~1605 | 1.87 | 1.38 |
| | wavenumber band) | | |
| Relative | ([CH₃]/[Si—O—Si])*100 | 8.39 | 2.49 |
| comparison | ([CH₃]/[Phenyl])*100 | 407.83 | 80.80 |
| value (%) | | | |

As shown in [Table 1], it can be seen that the second resin is calculated to have a much smaller relative value to the area integral value of other functional groups as well as the area integral value of the CH₃ functional group than the conventional resin. Since the area integral value at the corresponding wavenumber of each functional group can have an arbitrary unit, it can be analyzed that the relative comparison value of the area integral value to the other functional group is more meaningful than the area integral value of the functional group itself.

The relative comparison value of [CH₃ functional group area integral value]/[Si—O—Si functional group area integral value] in the conventional resin exceeds 5%. In the second resin, the relative comparison value of [CH₃ functional group area integral value]/[Si—O—Si functional group area integral value] is calculated to be smaller than or equal to 5%. For example, in the second resin, the relative comparison value of [CH₃ functional group area integral value]/[Si—O—Si functional group area integral value] can be calculated in a range of 2% to 3%.

In addition, the relative comparison value of [CH₃ functional group area integral value]/[phenyl functional group area integral value] in the conventional resin exceeds 100%. In the second resin, the relative comparison value of [CH₃ functional group area integral value]/[Phenyl functional group area integral value] is calculated to be smaller than or equal to 100%. For example, in the second resin, the relative comparison value of [CH₃ functional group area integral value]/[phenyl functional group area integral value] can be calculated in a range of 70% to 90%.

As described above, it can be seen that the resin applied to the light emitting device package according to the embodiment and the conventional resin have different characteristics. As described above, the silicone-based resin applied to the light emitting device package according to the embodiment can effectively seal the light emitting device. In addition, the silicone-based resin applied to the light emitting device package according to the embodiment can be stable to thermal changes and can prevent crack from occurring in the light emitting device package.

Meanwhile, the light emitting device package described above may be provided with a flip chip light emitting device as an example.

For example, the flip chip light emitting device may be provided as a transmissive flip chip light emitting device that emits light in six surface directions, or may be provided as a reflective flip chip light emitting device that emits light in five surface directions.

The reflective flip chip light emitting device that emits light in five surface directions may have a structure in which a reflective layer is disposed in a direction close to the package body 110. For example, the reflective flip chip light emitting device may comprise an insulating reflective layer, such as a Distributed Bragg Reflector, an Omni Directional Reflector, and the like and/or a conductive reflective layer such as Ag, Al, Ni, Au, and the like, between the first and second electrode pads and the light emitting structure.

In addition, the flip chip light emitting device that emits light in six surface directions may comprise a first electrode electrically connected to the first conductivity type semiconductor layer and a second electrode electrically connected to the second conductivity type semiconductor layer, and may be provided as a general horizontal light emitting device in which light is emitted between the first electrode and the second electrode.

In addition, the flip chip light emitting device that emits light in six surface directions may be provided as a transmissive flip chip light emitting device comprising both a reflective region between the first and second electrode pads in which a reflective layer is disposed and a transmissive region in which light is emitted.

Here, the transmissive flip chip light emitting device means a device that emits light to six surfaces comprising an upper surface, four side surfaces, and a lower surface. In addition, the reflective flip chip light emitting device means a device that emits light to five surfaces comprising an upper surface and four side surfaces.

Meanwhile, the light emitting device package according to the embodiment can be applied to the light source device.

Further, the light source device may comprise a display device, a lighting device, a head lamp, and the like depending on an industrial field.

As an example of the light source device, a display device may comprise a bottom cover, a reflector disposed on the bottom cover, a light emitting module comprising a light emitting device that emits light, a light guide plate disposed in front of the reflector and guiding light emitted from the light emitting module forward, an optical sheet comprising prism sheets disposed in front of the light guide plate, a display panel disposed in front of the optical sheet, an image signal output circuit connected to the display panel to supply an image signal to the display panel, and a color filter disposed in front of the display panel. In this case, the bottom cover, the reflector, the light emitting module, the light guide plate, and the optical sheet may constitute a backlight unit. In addition, the display device may not comprise a color filter, and may have a structure in which the light emitting device emitting red, green, and blue light are disposed, respectively.

As another example of the light source device, the head lamp may comprise a light emitting module comprising a light emitting device package disposed on a substrate, a reflector for reflecting light emitted from the light emitting module in a predetermined direction, for example, forward, a lens for refracting light reflected by the reflector forward, and a shade for constructing a light distribution pattern desired by designer by blocking or reflecting a portion of the light that is reflected by the reflector to be directed to the lens.

As another example of the light source device, the lighting device may comprise a cover, a light source module, a heat radiator, a power supply, an inner case, and a socket. In addition, the light source device according to an embodiment may further comprise at least one of a member and a holder. The light source module may comprise the light emitting device or the light emitting device package according to the embodiment.

Features, structures, effects and the like described in the above embodiments are comprised in at least one embodiment and are not limited to one embodiment only. Further, with respect to the features, structures, effects, and the like described in the embodiments, other embodiments may be carried out with combinations or modifications by those having ordinary skill in the art. Accordingly, the contents relevant to the combinations and modifications should be construed as being comprised in the scope of the embodiments.

Although preferable embodiments have been proposed and set forth in the aforementioned description, the present invention should not be construed as limited thereto. It will be apparent that various deformations and modifications not illustrated are available within the scope without departing from inherent features of the embodiment of the present invention by any one having ordinary skill in the art. For example, each component specifically shown in the embodiments may be carried out with the modifications. In addition, it is apparent that differences relevant to the modifications and deformations are comprised in the scope of the embodiments set in the accompanying claims of the present invention.

### INDUSTRIAL APPLICABILITY

According to the semiconductor device package and the method of manufacturing the semiconductor device package of the embodiments, there is an advantage that light extraction efficiency, electrical characteristics and reliability can be improved.

According to the semiconductor device package and the method of manufacturing the semiconductor device package of the embodiments, there is an advantage that manufacturing cost can be reduced and manufacturing yield can be improved by improving process efficiency and providing new package structure.

The semiconductor device package according to the embodiment has an advantage that the reflector can be prevented from being discolored by providing the body with high reflectance, thereby improving the reliability of the semiconductor device package.

According to the semiconductor device package and the method of manufacturing the semiconductor device of the embodiments, there is an advantage that re-melting phenomenon can be prevented from occurring in the bonding region of the semiconductor device package in the process of re-bonding the semiconductor device package to a board or the like.

1. A light emitting device package, comprising:
a body comprising first and second openings;
a light emitting device disposed on the body and comprising first and second bonding parts;
a first resin disposed between the body and the light emitting device; and
a second resin disposed on a side surface and an upper surface of the light emitting device,
wherein the second resin comprises functional groups detected in 800-850 wavenumber band, 929-1229 wavenumber band, and 1420-1605 wavenumber band, respectively, through FT-IR analysis, and
wherein [an area integral value of 800˜850 wavenumber band]/[an area integral value of 929˜1229 wavenumber band] is in a range of 2% to 3%, and [the area integral value of 800˜850 wavenumber band]/[an area integral value of 1420˜1605 wavenumber band] is in a range of 70% to 90%.

2. The light emitting device package of claim 1, wherein the first resin is disposed around the first and second bonding parts.

3. The light emitting device package of claim 1, comprising a recess provided on an upper surface of the body and disposed overlapped with the light emitting device, when viewed above the light emitting device.

4. The light emitting device package of claim 3, wherein the recess is provided at periphery of the first and second bonding parts.

5. The light emitting device package of claim 1, comprising a recess provided on an upper surface of the body and provided around the light emitting device to be overlapped with the second resin, when viewed above the light emitting device.

6. The light emitting device package of claim 5, wherein the second resin is provided in the recess.

7. The light emitting device package of claim 1, wherein lower surfaces of the first and second bonding parts are disposed lower than upper surfaces of the first and second openings.

8. The light emitting device package of claim 1, comprising a third resin disposed on an upper surface and a side surface of the second resin.

9. The light emitting device package of claim 1, comprising a conductor provided in the first and second openings and electrically connected with the first and second bonding parts, respectively.

10. A light emitting device package, comprising:
a body comprising first and second openings;
a light emitting device disposed on the body, and comprising a first bonding part disposed overlapped with the first opening in a vertical direction and a second bonding part disposed overlapped with the second opening in the vertical direction; and
a resin disposed on the body, and disposed on a side surface and an upper surface of the light emitting device,
wherein a boundary region in which an upper surface and a side surface of the resin are in contact with each other is provided in a curved shape,
wherein the resin comprises functional groups detected in 800-850 wavenumber band, 929-1229 wavenumber band, and 1420-1605 wavenumber band, respectively, through FT-IR analysis, and
wherein [an area integral value of 800˜850 wavenumber band]/[an area integral value of 929˜1229 wavenumber band] is in a range of 2% to 3%, and [the area integral value of 800˜850 wavenumber band]/[an area integral value of 1420˜1605 wavenumber band] is in a range of 70% to 90%.

11. The light emitting device package of claim 10, wherein lower surfaces of the first and second bonding parts are disposed lower than upper surfaces of the first and second openings.

12. The light emitting device package of claim 10, comprising a conductor provided in the first and second openings and electrically connected with the first and second bonding parts, respectively.

13. The light emitting device package of claim 12, wherein the conductor is disposed in contact with a side surface and the lower surface of the first bonding part in the first opening, and
wherein the conductor is disposed in contact with a side surface and the lower surface of the second bonding part in the second opening.

14. A light emitting device package, comprising:
a body comprising first and second openings passing through an upper surface and a lower surface thereof, and a side wall proving a cavity;
a light emitting device disposed in the cavity of the body, and comprising a first bonding part disposed to overlap with the first opening in a vertical direction and a second bonding part disposed to overlap with the second opening in the vertical direction;
a first resin disposed between the body and the light emitting device; and
a second resin disposed on a side surface and an upper surface of the light emitting device,
wherein the second resin comprises functional groups detected in 800-850 wavenumber band, 929-1229 wavenumber band, and 1420˜1605 wavenumber band, respectively, through FT-IR analysis, and
wherein [an area integral value of 800˜850 wavenumber band]/[an area integral value of 929˜1229 wavenumber band] is in a range of 2% to 3%, and [the area integral value of 800˜850 wavenumber band]/[an area integral value of 1420˜1605 wavenumber band] is in a range of 70% to 90%.

15. The light emitting device package of claim 14, wherein the first resin is disposed around the first and second bonding parts.

16. The light emitting device package of claim 15, wherein the first resin is disposed in direct contact with a side surface of the first bonding part, and
wherein the first resin is disposed in direct contact with a side surface of the second bonding part.

17. The light emitting device package of claim 14, comprising a recess provided on an upper surface of the body and provided around the light emitting device to be overlapped with the second resin, when viewed above the light emitting device.

18. The light emitting device package of claim 17, wherein the second resin is provided in the recess.

19. The light emitting device package of claim 14, comprising a conductor provided in the first and second openings and electrically connected with the first and second bonding parts, respectively.

20. The light emitting device package of claim 19, wherein the conductor is disposed in contact with side and lower surfaces of the first bonding part in the first opening, and
wherein the conductor is disposed in contact with side and lower surfaces of the second bonding part in the second opening.
